(19) United States
(12) Patent Application Publication
(10) Pub. No.: US 2014/0308793 A1
(43) Pub. Date: Oct. 16, 2014

(54) Varactor Diode, Electrical Device and Method for Manufacturing Same

(71) Applicant: Infineon Technologies AG, Neubiberg (DE)

(72) Inventors: Josef Dietl, Muenchen (DE); Raimund Peichl, Hoehenkirchen-Siegertsbrunn (DE); Gabriele Bettineschi, Muenchen (DE)

(21) Appl. No.: 14/318,118

(22) Filed: Jun. 27, 2014

Related U.S. Application Data
(62) Division of application No. 13/667,996, filed on Nov. 2, 2012.

(51) Int. Cl. H01L 29/93; H01L 21/326

(52) U.S. Cl. CPC H01L 29/93; H01L 21/326
USPC 438/379; 438/466

(57) ABSTRACT

An electrical device includes a semiconductor material. The semiconductor material includes a first region of the semiconductor material having a first conductivity type, a second region of the semiconductor material having a second conductivity type complementary to the first conductivity type and an intermediate region of the semiconductor material between the first region and the second region. The first and second regions lie next to each other the intermediate region so as to form a diode structure. A shape of the intermediate region tapers from the first region to the second region.

This is a divisional application of U.S. application Ser. No. 13/667,996, entitled “Varactor Diode, Electrical Device and Method for Manufacturing Same” which was filed on Nov. 2, 2012 and is incorporated herein by reference.

### TECHNICAL FIELD

Embodiments refer to an electrical device and a method for manufacturing same. Further embodiments refer to a varactor diode.

### BACKGROUND

A varactor diode is an electrical device having a variable capacitance. The capacitance of the diode may be varied by varying an applied voltage to same when the varactor diode is operated reverse biased so that no current flows through same. Background thereof is that a variation of the applied voltage (e.g., DC voltage) leads to a variation of a thickness of the depleted zone. Typically, the depleted zone thickness is proportional to the square root of the applied voltage, wherein the capacitance is inversely proportional to the depleted zone thickness. Consequently, the capacitance is inversely proportional to the square root of the applied voltage. Applications of such a varactor diode cover a broad spectrum comprising applications like tuning diodes for parametric amplifiers, voltage-controlled oscillators (VCO), phase-locked loops (PLL) or frequency synthesizers.

### SUMMARY OF THE INVENTION

Embodiments of the present invention provide an electrical device comprising a semiconductor material. The electrical device further comprises a first region of the semiconductor material having a first conductivity type, a second region of the semiconductor material having a second conductivity type complementary to the first conductivity type and an intermediate region of the semiconductor material between the first region and the second region. The first and second regions lie next to each other via the intermediate region so as to form a diode structure. A shape of the intermediate region tapers from the first region to the second region.

A further embodiment provides an electrical device comprising a semiconductor material. The semiconductor material comprises a first region of the semiconductor material having a first conductivity type, a second region of the semiconductor material having a second conductivity type complementary to the first conductivity type and an intermediate region of the semiconductor material of the second conductivity type between the first region and the second region so that the first and the second regions lie next to each other via the intermediate region so as to form a diode structure. A ratio between a first area forming a junction between the intermediate region and the first region, and second area forming a further junction between the intermediate region and the second region is at least 2:1. A doping concentration of the intermediate region is equal or larger than 10¹⁵.

A further embodiment provides a varactor diode comprising a substrate on which a semiconductor material is arranged. The semiconductor material comprises a first region of the semiconductor material having a p-doping, a second region of the semiconductor material having an n-doping and an intermediate region of the semiconductor material between the first region and the second region. Thus, the first and the second regions lie next to each other via the intermediate region so as to form a lateral diode structure having a capacitance between the first and the second region which is variable dependent on a voltage applied in a reverse direction between the first and the second region. The first region, the intermediate region, and the second region are laterally arranged along the forward direction extending from the first region to the second region, the forward direction lying in parallel to a main surface of a substrate. A shape of the intermediate region tappers from the first region to the second region such that a ratio between a first area forming a junction between the intermediate region and the first region, and second area forming a further junction between the intermediate region and the second region is at least 2:1. The intermediate region has a volume comprising a plurality of boundary surfaces, wherein two boundary surfaces facing each other are defined by the first and the second areas forming the junctions and wherein two further boundary surfaces are concave and laterally limited by trenches surrounding the intermediate region.

A further embodiment provides an electrical device comprising a semiconductor material. The semiconductor material comprises a first region of the semiconductor material having a first conductivity type, an intermediate region of the semiconductor material of a second conductivity type, complementary to the first conductivity type, embedded into the first region and a second region of the semiconductor material having the second conductivity type. The second region is embedded into the intermediate region so that the first and the second regions lie next to each other via the intermediate region so as to form a diode structure. A doping concentration of the intermediate region is equal or larger than 10¹⁵.

A further embodiment provides a method for manufacturing an electrical device. The method comprises providing a semiconductor material, providing a first region having a first conductivity type into the semiconductor material and providing a second region having a second conductivity type complementary to the first conductivity type into the semiconductor material. Further, a method comprises providing an intermediate region of the semiconductor material between the first region and the second region so that the first and the second regions lie next to each other via the intermediate region so as to form a diode structure. A shape of the intermediate region tapers from the first region to the second region.

### BRIEF DESCRIPTION OF THE DRAWINGS

Embodiments of the invention will be discussed referring to the drawings, wherein:

FIG. 1a shows a schematic 3D view of an electrical device illustrating a first aspect of an embodiment;

FIG. 1b shows a schematic 3D view of an electrical device illustrating a second aspect of the embodiment of FIG. 1a;

FIGS. 2a and 2b show schematic top views of electrical devices according to embodiments;

FIG. 2c shows a schematic cross-sectional view of one of the embodiments of

FIGS. 2a and 2b in which the intermediate region is formed by a well;

FIG. 3a shows a schematic top view of an electrical device according to an embodiment in which the first region is formed by a substrate;

FIG. 3b shows a schematic cross-sectional view of the embodiment of FIG. 3a;

FIG. 3c shows a schematic top view of an electrical device according to an embodiment in which the first region is formed by a substrate; and

FIG. 3d shows a schematic cross-sectional view of the embodiment of FIG. 3c.

### DETAILED DESCRIPTION OF ILLUSTRATIVE EMBODIMENTS

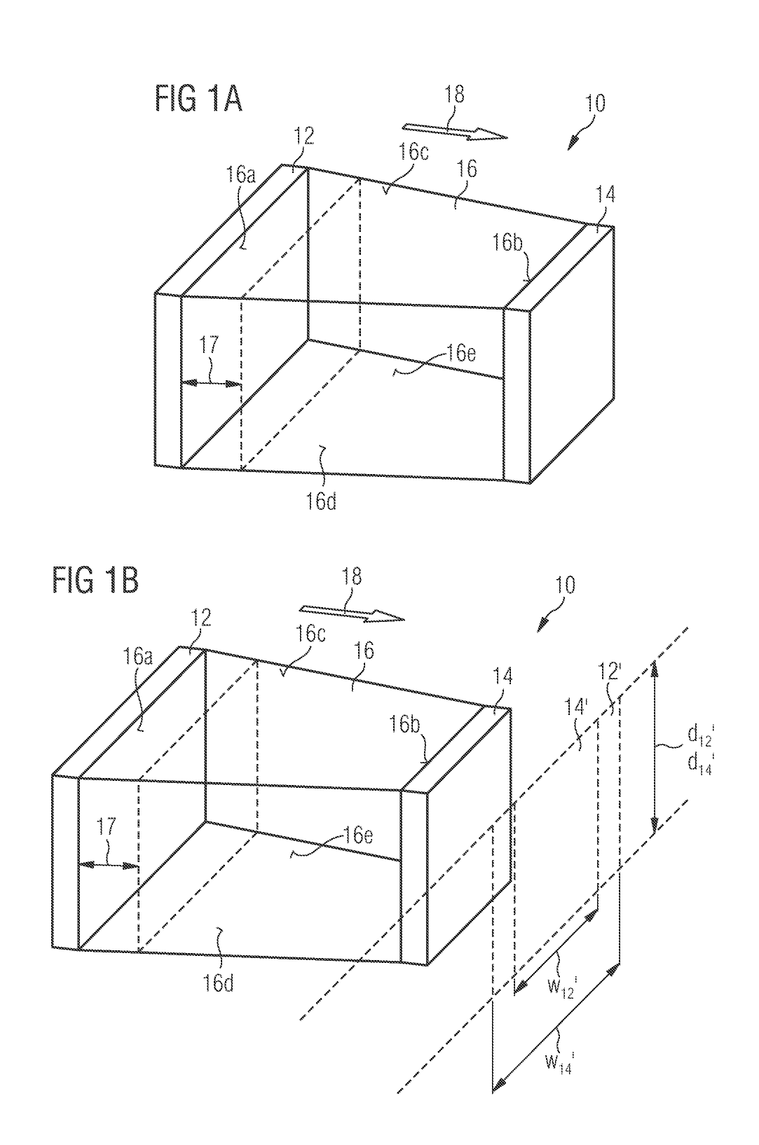

Different embodiments of the teachings disclosed herein will subsequently be discussed referring to FIG. 1 to FIG. 3. Below, identical reference numbers are provided to objects having identical or similar functions so that objects referred to by identical reference numbers within the different embodiments are interchangeable and the description thereof is mutually applicable.

FIGS. 1a and 1b show schematic 3-dimensional views of an electrical device 10, wherein two different aspects of the invention will be discussed with respect to FIG. 1a and FIG. 1b. The electrical device 10 comprises a semiconductor material, wherein at least three regions, namely a first region 12, a second region 14 and an intermediate region 16, are provided to the semiconductor material. The three regions 12, 14 and 16 are arranged such that the intermediate region 16 lies between the first region 12 and the second region 14. Please note that the two illustrated regions 12 and 14 of the semiconductor material, which typically have a 3-dimensional shape influenced by the manufacturing process, are simplified as cubics, wherein the volume between these two cubics forms the intermediate region 16.

The first region 12 is of a first conductivity type and may, for example, comprise a p+ doping. The second region 14 is of a second conductivity type complementary to the first conductivity type and may, for example, comprise an n+ doping. As indicated by the “+”, the first and second region 12 and 14 may have a high doping concentration, e.g., in a range 10⁻¹⁸ to 10⁻¹⁹ (cf. diffusion or diff contacted sinker). In contrast, the intermediate region 16 (e.g., an nv or hv well or other), which may be of the second conductivity type (e.g., n-doping), may have a low doping concentration which is typically 10 times to 100 times smaller when compared to the doping concentration of the first or second region 12 and 14, i.e., in a range between 10⁻¹⁵ to 10⁻¹⁷.

The two regions 12 and 14 lying next to each other via the intermediate region 16 form a diode structure having a forward direction 18 extending from the first region 12 to the second region 14. Note that both regions 12 and 14 may be contacted by proper diffusion contacts, wherein the intermediate region 16 is not contacted. This diode structure 10 (pn-diode structure) may be used as a varactor diode structure which is configured to adjust its capacitance as a function of the applied (DC) voltage between the two regions 12 and 14, if the diode structure 10 is reverse biased. Basically, the capacitance depends on the areas of the two regions 12 and 14 and on a thickness of the depleted zone 17 (illustrated by broken lines) formed between the two regions 12 and 14, i.e., within the intermediate region 16. As explained above, this thickness may depend on the applied voltage between the two regions 12 and 14 so that the capacitance of the electrical device 10 may be adjustable via this (DC) voltage. Note that the depleted zone 17 extends from a first junction between the first region 12 and the intermediate region 16 to a second junction between the intermediate region 16 and the second region 14 (cf. forward direction 18), when the applied voltage is increased. As mentioned, the operating mode as a varactor diode is based on the fact that the diode structure 10 is reversed biased, so when a voltage is applied in the reverse direction (which is opposite to a forward direction 18) and when the voltage is below the device specific avalanche voltage.

For example, the electrical device 10 may be reverse biased in case of the above described doping configuration (p+ doping for the first region 12 and n+ doping for the second region 14) when the electrical potential (+vᵣ) applied to the second region 14 is more positive when compared to the potential (e.g., ground) applied to the first region 12. Alternatively, the electrical device 10 may also be reverse biased when the electrical potential of the second region 14 is more negative when compared to the electrical potential of the first region 12 in case of an opposite doping configuration (for example, when the first region 12 comprises n+ dopants and when the second region 14 comprises p+ dopants). As discussed above, this electrical device 10 may be used as a varactor diode or tuning diode, for example, in an RC-circuit for a high frequency receiver or in a voltage controlled oscillator. Consequently, in such applications, the applied DC voltage (control voltage) may be overlaid by an AC voltage. This AC voltage does not substantially influence the thickness of the depleted zone due to its high frequency so that the capacitance depends mainly on the applied DC voltage (+vᵣ), because the AC voltage is typically smaller than the DC voltage. However, current varactor diodes have a small range in which the capacitance may be adjusted.

In order to increase this range, the geometry of the shown electrical device 10 is optimized according to the first aspect, which is illustrated by FIG. 1a. Here, the intermediate region 16 is provided such that same tapers from the first region 12 to the second region 14. Due to this tapered geometry of the intermediate region 16 the shape of the depleted zone is influenced such that the leverage of the applied DC voltage to the adjustable capacitance is increased. Background thereof is that the tapered geometry leads to a necking of the depleted zone 17 in case of an increased control voltage and thus to an disproportional increase of the thickness of the depleted zone 17. This exponential increase of the depleted zone 17 leads to an exponential increase or exponential adjustability of the capacitance of the electrical device 10.

The intermediate region 16 may be a volume having a plurality (five or six) of boundary surfaces, wherein two boundary surfaces 16a and 16b facing each other are arranged such that same are directly connected to the regions 12 and 14, respectively. In turn, this means that the boundary surface 16a is formed by the junction between the first region 12 and the intermediate region 16, while the boundary surface 16b is formed by the junction between the second region 14 and the intermediate region 16. The volume of the intermediate region 16 comprises two further (lateral) boundary surfaces 16c and 16d arranged such that same extend from the first region 12 to the second region 14 and face each other. The dimension of the two further boundary surfaces 16c and 16d is defined by a depth d_{12′} and d_{14′} of the two portions 12 and 14 as well as by the distance between the two regions 12 and 14. It should be noted that this volume 16 may have a fifth (flat) boundary surface 16e. The fifth (flat) boundary surface 16e facing to the main surface of the electrical device 10 may have a flowing transition to the next (lower) layer. Typically the boundary surfaces 16c, 16d and 16e are isolated against the surrounding (substrate, etc.), e.g., by an oxide trench, as will be discussed below. Further, the outer boundary surfaces of the first and second region 14 and 16 may also be isolated against the surrounding.

FIG. 1b shows the optimization of the geometry of the electrical device 10 according to the second aspect. The two regions 12 and 14 are provided such that a first projection area 12′ of a first region 12 differs from a second projection area 14′ of the second region 14 when the two regions 12 and 14 are projected into each other along a forward direction 18. Due to the two different projection areas 12′ and 14′ the intermediate region 16 between the two regions 12 and 14 forms the transition region which tapers in the forward direction 18, as explained above. Consequently, the two projection areas 12′ and 14′ define the two facing surface areas 16a and 16b of the intermediate region 16 and, thus, the junctions of the surface areas 16a and 16b. Due to the geometry substantially defined by the two regions 12 and 14 the formation depleted zone 17 is influenced such that latter is necked, as discussed above.

As shown, the respective areas 12′ and 14′ depend on its width w_{12′} and w_{14′}, respectively, and on its depth d_{12′} and d_{14′}, respectively. In this implementation, the depth d_{12′} and d_{14′} may be substantially equal to each other so that the difference of the projection areas 12′ and 14′ is mainly based on the different width w_{12′} and w_{14′} of the two projection areas 12′ and 14′. To put it simply, this means that the widths w_{12′} and w_{14′} of the respective regions 12, 16 and 14 decrease in the forward direction 18 so that a ratio between the width w_{12′} and the width w_{14′} may, for example, amount to 3:1 or 5:1 or, in general, may be larger than 1.5:1 or 2:1. Please note that these two aspects may, probably, be combined.

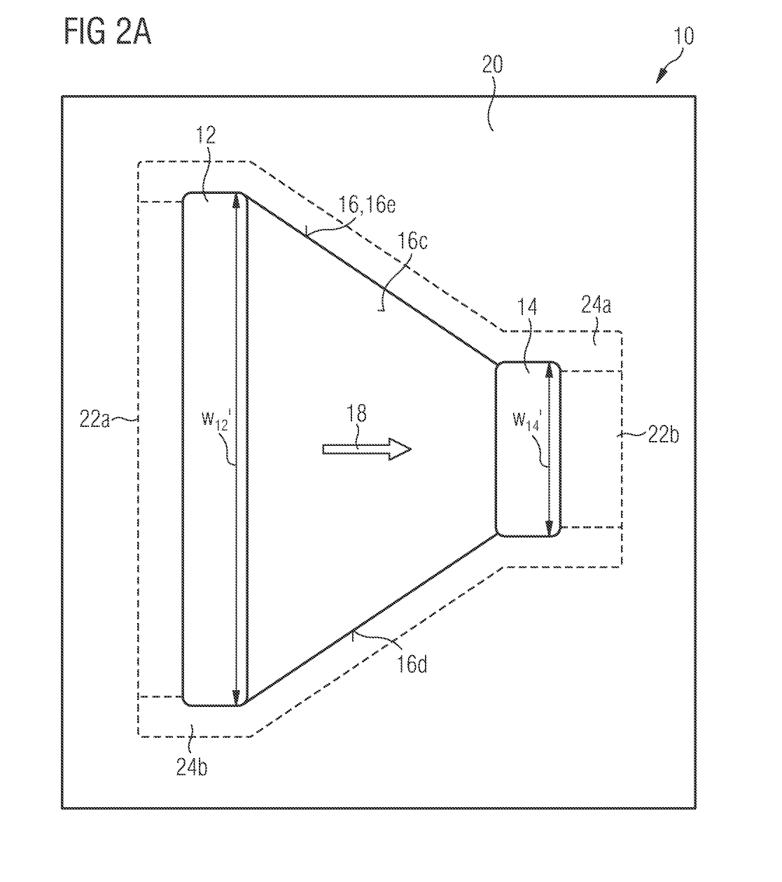

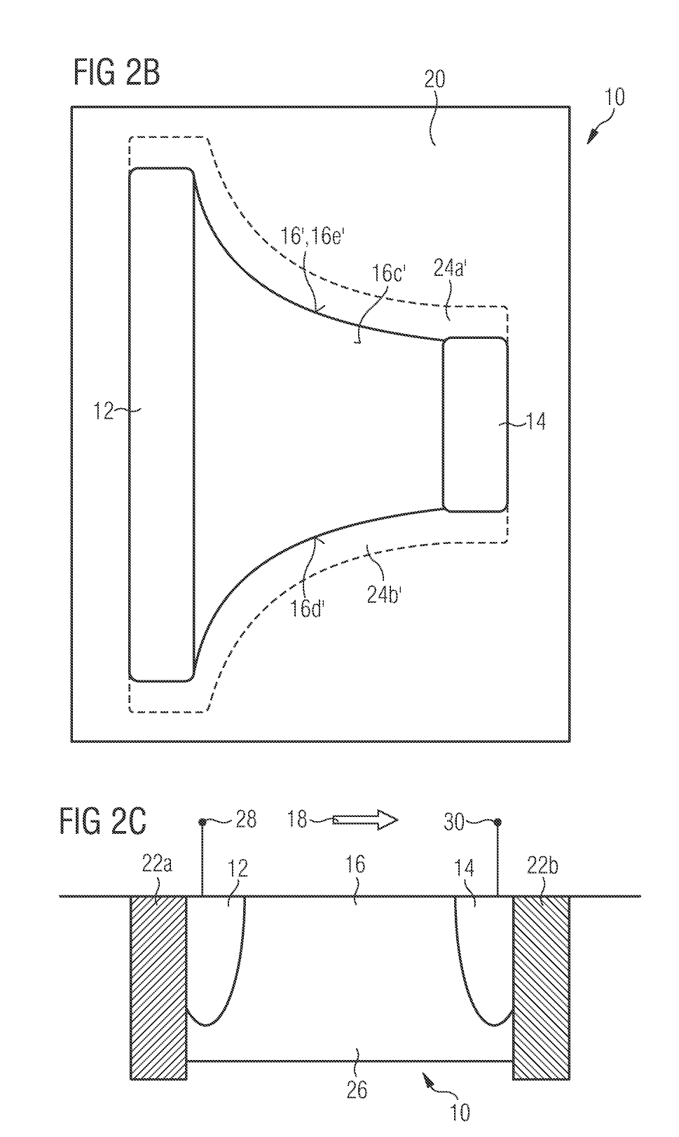

FIG. 2a shows the electrical device 10 in a top view. Here, the first, second and intermediate regions 12, 14 and 16 of the semiconductor material are laterally arranged along the forward direction 18 which is in parallel to a main surface of a substrate 20 to which the semiconductor material is provided or which comprises the semiconductor material. As illustrated, the width w_{12′} and the projection area 12′, respectively, may, for example, be at least 50% larger than the width w_{14′} and the projection area 14′, respectively.

Consequently, the two further boundary surfaces 16c and 16d converge, wherein it should be noted that in this implementation the two further boundary surfaces 16c and 16d are approximately flat surfaces so that its edges shown in this top view (cf. edges of the boundary surface 16e) are preferably but not necessarily straight.

According to a further implementation oxide trenches 22a, 22b, 24a and 24c may be provided such that same surround the three regions 12, 14 and 16. The oxide trenches 22a, 22b, 24a and 24c serve the purpose to insulate the electrical device 10 and, especially, the two regions 12 and 14 against the surrounding, e.g., against a substrate or against a well into which the electrical device 10 is provided.

Below, a method for manufacturing this implementation of the electrical device 10 will be described. The method comprises the steps of providing the semiconductor material on the substrate 20 or providing the substrate 20, which comprises the semiconductor material. Into this semiconductor material the intermediate region 16 is provided before providing the first and the second region 12 and 14. Please note that the two regions 12 and 14 are provided such that same have the complementary conductivity type, wherein the intermediate region 16 is of the conductivity type of the second region 14 (Background: This conductivity type configuration enables that the depleted zone 17 may extend form the first region 12 to the second region 14 in the forward direction 18 in case of increasing the DC voltage +Vᵣ). The first region 12 having the larger projection area 12′ has preferably the first conductivity type (e.g., p+ doped) such that same forms the anode. This step of doping the regions 12, 14 and/or 16 may comprise vapor phase epitaxy or doping by using diffusion or ion implantation. In order to limit the lateral arrangement on the substrate 20, the steps of providing the first, second and intermediate regions 12, 14 and 16 may be based on photolithography.

According to another implementation of the manufacturing process, the optional trenches 22a and 22b, e.g., filled with oxide, may be provided along the forward direction 18 in order to limit the two regions 12 and 14. Further, in order to define the width w_{12′} and the width w_{14′} as well as the lateral shape of the intermediate region 16 (cf. boundary surface 16c and 16d) the further oxide trenches 24a and 24b may be provided which extend along the forward direction 18 such that the oxide trenches 22a, 22b, 24a and 24b laterally surround at least the intermediate portion 16. Alternatively, the oxide trenches 22a, 22b, 24a and/or 24c may be provided after providing the three or at least one of the three regions 12, 14 and 16 so that the lateral shape of same may be defined afterwards.

FIG. 2b shows a further top view of electrical device 10′ provided to the substrate 20. In this implementation the two further boundary surfaces 16c′ and 16d′ of the intermediate region between the first and second region 12 and 14 are concave (cf. curved edges adjacent to the boundary surface 16e′). Alternatively, also convex boundary surfaces 16c′ and 16d′ are possible. This enables an improved forming of the depleted zone in the intermediate region 16′ when a voltage is applied between the two regions 12 and 14.

Referring to the above described manufacturing process it should be noted that the optional oxide trenches 24a′ and 24b′ may have a shape of an e-function in this implementation in order to form the concave boundary surfaces 16c′ and 16d′.

FIG. 2c shows a cross-section view of the electric device 10 or 10′ of the representation of FIG. 2a or 2b. Here, the semiconductor material is provided to the substrate 20 (e.g., a p-substrate or isolating substrate), for example by using epitaxy. The semiconductor material forms a well, for example an n-doped well 26 to which the first region 12 and the second region 14 are provided. The two regions 12 and 14 embedded into the well 26 may have the shape of a drop. Each of the two regions 12 and 14 having the different projection area when projected to each other may comprise optional terminals 28 and 30 for applying the voltage between the two regions 12 and 14. The intermediate region 16 is formed between the first and the second region 12 and 14 within the well 26. Expressed in other words, that means that the well 26 forms the intermediate region 16 so that same is of the conductivity type of the well 26. As illustrated, the depth w₁₂ and w₁₄ of the two regions 12 and 14 extend over more than 50% of the thickness of the well 26 and vice versa do not necessary extend over the entire thickness of same. Due to the isolating substrate 20 onto which the regions 12, 14 and 16 are formed a so-called silicon on insulator (SOI) is formed. If no insolating substrate 20 may be used, an oxide layer and the above mentioned oxide trenches may be arranged between the substrate 20 and the intermediate region 16 in order to isolate the electrical device 10 or 10′ against the substrate.

As illustrated, the three regions, namely the first, second and intermediate regions 12, 14 and 16 may optionally be laterally limited in the forward direction 18 by the oxide trenches 22a and 22b. As discussed with respect to FIGS. 2a and 2b the optional oxide trenches 22a and 22b may be provided to the semiconductor material and/or to the substrate 20 before or after the providing the regions 12, 14 and/or 16.

According to another implementation, the intermediate region 16 may have a doping profile in order improve the controllability of the depleted zone. This doping profile may vary along the forward direction 18 (lateral dopant profile) and or along a further direction perpendicular to the substrate 20. Note that the doping profile may preferably vary in the direction perpendicular to the substrate 20. In case of a doping profile the average doping concentration of the intermediate region 16 is reduced by 10⁻² or 10⁻³ when compared to the doping concentration of the first or second region 12 and 14.

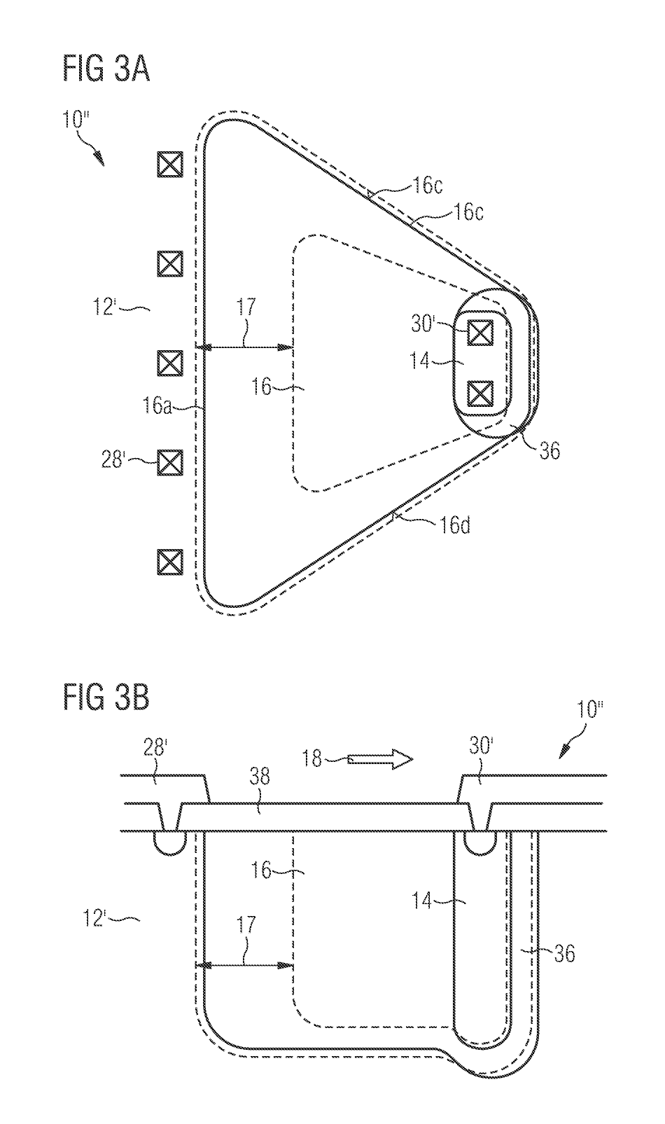

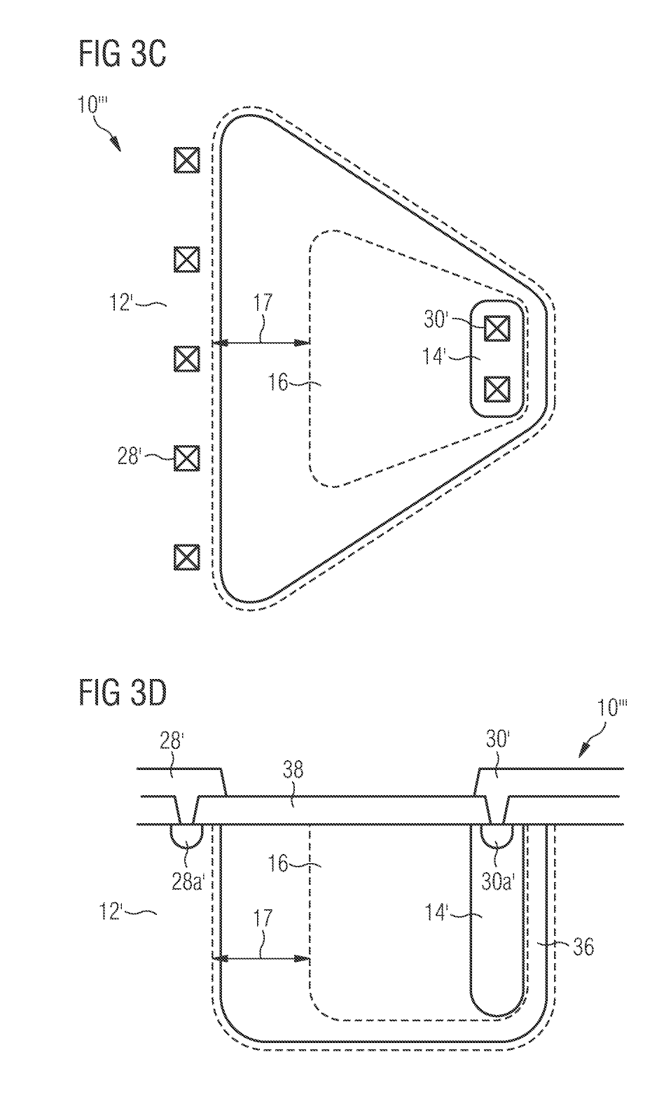

FIGS. 3a and 3b show a further implementation of an electrical device 10″, wherein FIG. 3a illustrates a top view and FIG. 3b a cross-sectional view of same. The electrical device 10″ comprises a first region 12′ which is formed by the substrate, wherein the second region 14 and the intermediate region 16 are embedded into the substrate. The intermediate region 16 formed as a well lies adjacent to the second region 14 and has a conical shape (cf. FIGS. 1a and 1b). Thus, the intermediate region 16 in which the depleted zone 17 (illustrated by broken lines) shall be formed is surrounded by the first region 12′, wherein the second region 14 is in contact with the intermediate region 16 at a first site and shielded by a shield 36 at a second site. The shield 36 is formed between the second region 14 and the first region 12′ along the entire junction between these two regions 12′ and 14. The shield 36 may be of the same conductivity type of the first region 12′, but may have a low doping concentration (e.g., p-doping).

The purpose of the shield 36 is avoiding a direct avalanche between the first region 12′ and the second region 14′. Due to the shield 36, the depleted zone 17 is formed within the intermediate region 16 in the reverse direction (complementary to the forward direction 18) when the electrical device 10′ is reversely biased. As shown the depleted zone 17 is formed along the entire junction (cf. surfaces 16a, 16c and 16d) between the first region 12′ and the intermediate 16, wherein the thickness of same is larger at the boundary surface 16a when compared to the boundary surfaces 16c and 16d.

In this implementation the first and second region 12′ and 14 are electrically contacted by plurality of contacts, namely the contact 28′ for the first region 12′ and the contact 30′ for the second region 14. As illustrated by FIG. 3b, the contacts 28′, 30′ are formed by a metal layer, e.g., alloy, which extends through an insulating oxide layer 38 provided to the surface of the electrical device 10′.

FIGS. 3c and 3d illustrate a further implementation of an electrical device 10″'. Here, the first region 12′ is formed by the substrate, in which the intermediate region 16 (well) having a conical shape is embedded, wherein the second region 14′ (sinker) is embedded into the intermediate region 16. Thus, the material junction between the first region 12′ and the intermediate region 16 is formed along the entire outer surface of the intermediate region 16, wherein the junction between the second region 14′ and the intermediate region is formed at its inside surfaces.

Consequently, the depleted zone 17 extends along the entire outside surfaces of the intermediate region 16 when the electrical device 10′ is reversely biased. The depleted zone 17 is mainly formed within the intermediate region 16, wherein a small portion of the depleted zone 17 extends into the first region 12′. This leads to a high variation of the area of the depleted zone 17 and thus to a necking of the depleted zone 17, which, in turn, leads to a high leverage of the variable capacitance.

This implementation of the electrical device 10′″ may, optionally, comprise the contacts 28′ and 30′ provided at the main surface of the electrical device 10′, wherein an optional diffusion region 28a′ and 30a′ may be arranged at the contacts 28′ and 30′. These diffusion regions 28a′ and 30a′, which are embedded into the respective first and second regions 12′ and 14′, may be of the same conductivity type of the respective region 12′ or 14′, but may have a higher doping concentration (e.g., n++ of p++).

According to further implementation the intermediate region 16 of the electrical device 10″' may have another shape, e.g., the shape of an ellipsis, wherein the second region 14′ is arranged preferably non-axially (non-concentrically) in the later plane within the intermediate region 16. Due to the non-axial arrangement the necking of the depleted zone 17 is caused by the geometry in case of an applied control voltage between the two regions 12′ and 14′. Background thereof is that the depleted zone 17 radially extends from the junction between the first region 12′ and the intermediate region 16 to the second region 14′ (cf. (FIGS. 3c and 3d), wherein the non-symmetric geometry of the electrical device 10″' causes the necking of the thickness of the depleted zone 17 and, thus, an adjustable capacitance having a high leverage, as explained above. In general, the three regions 12′, 14′ and 16 are arranged such that the second region 14′ lies within the intermediate region 16 and such that around a center of areal gravity of the second region 14′ a distance between the first region 12 and the second region 14′ defined by the intermediate region 16 varies. So, the distance varies dependent on an azimuth angle around the areal gravity of the second region 14′. Here, the distance is defined by a respective point of the outer surface (cf. junction between the first region 12 and the intermediate region 16) at the respective azimuth angle and the closest point of the first region 12′ measured from the respective point at the outer surface.

According to further implementation, the second region 14′ is concentrically arranged within the intermediate region 16 (lying within the first region 12′), wherein same may also a circular shape. Due to the concentric arrangement of the two regions 14′ and 16 the junction area between the second region 14′ and the intermediate region 16 is significantly smaller than the junction area between the intermediate region 16 and the first region 12′. So, this leads to the same effect of the necking of the depleted zone 17, as discussed above.

Regarding FIGS. 1a and 2b, it should be noted that the two regions 12 and 14 of the semiconductor material which are illustrated as cuboids may have an alternative geometry deviating from the shown regular geometry, e.g., a rounded geometry or geometry of drop (cf. FIG. 2c).

Regarding FIGS. 1a and 1b it should be noted that the first junction is defined by a change of the conductivity type and of the doping concentration, wherein the second junction is defined by a change of the doping concentration.

Although implementations of this invention have been described in context of a lateral (varactor) diode, it should be noted that the structure of the electrical device may be arranged vertically within the semiconductor material. Such a device may, for example, be manufactured by providing a cone shaped trench having undercuts to the semiconductor material and by filling the trench such that the first and the second region are formed in different layers, wherein the intermediate region lies between the first and the second region.

What is claimed is:

1. A method for adjusting a capacitance of an electrical device comprising a semiconductor material, the electrical device comprising:
a first region of the semiconductor material having a first conductivity type;
a second region of the semiconductor material having a second conductivity type complementary to the first conductivity type; and
an intermediate region of the semiconductor material between the first region and the second region so that the first and the second regions lie next to each other via the intermediate region so as to form a lateral diode structure having a capacitance between the first region and the second region, wherein a shape of the intermediate region tapers from the first region to the second region,
the method comprising the step of applying an voltage between the first and the second region in a reversed biased manner, wherein the capacitance depends on the applied voltage.

2. The method according to claim 1, wherein a width of the intermediate region decreases from the first region to the second region.

3. The method according to claim 1, wherein a ratio between a first area forming a junction between the intermediate region and the first region, and a second area forming a further junction between the intermediate region and the second region is at least 2:1.

4. The method according to claim 1, wherein the intermediate region has a volume comprising a plurality of boundary surfaces, wherein two boundary surfaces facing each other are defined by junction areas to the first and the second region.

5. The method according to claim 4, wherein two further boundary surfaces of the plurality of boundary surfaces converge.

6. The method according to claim 4, wherein two further boundary surfaces of the plurality of boundary surfaces are concave.

7. The method according to claim 1, wherein the first and the second regions are projected into each other along a forward direction, wherein a first projection area of the first region and a second projection area of the second region differ from each other.

8. The method according to claim 7, wherein the first projection area is at least 50% larger than the second projection area.

9. The method according to claim 7, wherein the first projection depends on a first width and a first depth of same and wherein the second projection depends on a second width and a second depth of same, and wherein the first width is at least 50% larger than the second width.

10. The method according to claim 5, wherein the two further boundary surfaces are laterally limited by trenches surrounding the intermediate region.

11. The method according to claim 1, wherein the semiconductor material is disposed in a substrate.

12. The method according to claim 11, wherein the first region, the intermediate region and the second region are laterally arranged along a forward direction that lies in parallel to a main surface of the substrate.

13. The method according to claim 11, wherein the semiconductor material is arranged on the substrate, the substrate being a low doped substrate or and isolating substrate.

14. The method according to claim 11, wherein the intermediate region is of the second conductivity type.

15. The method according to claim 1, wherein the first conductivity type comprises a p-doping and wherein the second conductivity type comprises a n-doping such that the forward direction extends from the first region to the second region.

16. The method according to claim 1, wherein the intermediate region is formed by a well or a low doped well.

17. The method according to claim 16, wherein the first region and the second region extend into the well up to a depth which is smaller than a depth of the well.

18. The method according to claim 1, wherein the first region is formed by a well or high doped well or a high doped substrate.

19. The method according to claim 12, wherein the first region and the second region are laterally limited by trenches that are arranged perpendicular to the forward direction.

20. The method according to claim 1, wherein the intermediate region comprises a doping profile which varies along the forward direction and/or along a further direction perpendicular to the forward direction.

21. The method according to claim 1, wherein a doping concentration of the intermediate region is maximally 100 times smaller when compared to a doping concentration of the first or/and of the second region.

22. The method according to claim 1, wherein the first region comprises a first contact or diffusion contact and wherein the second region comprises a second contact or diffusion contact.

23. The method according to claim 1, further comprising:
a RC-circuit comprising a resistor connected in series with the electrical device; and
using a controller, controlling the capacitance of the electrical device via a control voltage applied between the first region and the second region.

24. A method for adjusting a capacitance of a varactor diode comprising a substrate on which a semiconductor material is arranged, the semiconductor material comprising:
a first region having a p-doping;
a second region having a n-doping; and
an intermediate region between the first region and the second region so that the first and the second regions lie next to each other via the intermediate region so as to form a lateral diode structure having a capacitance between the first and the second region, the capacitance being variable dependent on a voltage applied in a reverse direction between the first and the second region;
wherein the first region, the intermediate region and the second region are laterally arranged along the forward direction extending from the first region to the second region and lying in parallel to a main surface of the substrate;
wherein a shape of the intermediate region tapers from the first region to the second region such that a ratio between a first area forming a junction between the intermediate region and the first region and a second area forming a further junction between the intermediate region and the second region is at least 2:1; and
wherein the intermediate region has a volume comprising a plurality of boundary surfaces, wherein two boundary surfaces facing each other are defined by the first and the second areas forming the junctions and wherein two further boundary surfaces are concave and laterally limited by trenches surrounding the intermediate region.

25. A method for adjusting a capacitance of an electrical device comprising a semiconductor material, the electrical device comprising:
a first region of the semiconductor material having a first conductivity type;
an intermediate region of the semiconductor material of a second conductivity type, complementary to the first conductivity type, embedded into the first region; and
a second region of the semiconductor material having the second conductivity type,
wherein the second region is embedded into the intermediate region so that the first and the second regions lie next to each other via the intermediate region so as to form a diode structure,
wherein a doping concentration of the intermediate region is equal or larger than 10¹⁵,
wherein the second region is arranged within the intermediate region, wherein the intermediate region has an axial shape of an ellipse, wherein a distance between the first region and the second region defined by the intermediate region varies around a center of areal gravity of the second region; and
the method comprising the step of applying voltage between the first and the second region in a reversed biased manner, wherein the capacitance depends on the applied voltage.

26. The method of claim 25, further comprising:
a RC-circuit comprising a resistor connected in series with the electrical device; and
using a controller, controlling the capacitance of the electrical device via a control voltage applied between the first region and the second region.

27. A method for adjusting a capacitance of an electrical device, the electrical device comprising:
a first region disposed in a semiconductor substrate, the first region having a first doping type;
an intermediate region of a second doping type disposed in the semiconductor substrate, the second doping type being an opposite type of doping to the first doping type, wherein the intermediate region is within the first region;
a second region having the second doping type disposed in the semiconductor substrate, the second region disposed within the intermediate region, wherein the intermediate region is disposed between the first region and the second region, wherein the first region comprises four sides in a top view, wherein the intermediate region comprises four sides in the top view, wherein, in the top view, each side of the first region faces a corresponding side of the intermediate region, wherein, in the top view, a nearest distance from each side of the intermediate region to the corresponding side of the first region facing the side of the intermediate region varies along the perimeter of the intermediate region; and
the method comprising applying voltage, between the first and the second region, in a reversed biased manner.

28. The method according to claim 27, wherein the second region has an elliptical shape in a top view, wherein a nearest distance from a perimeter of the second region to a perimeter of the first region varies along the perimeter of the second region.

29. The method according to claim 27, wherein the capacitance varies exponentially with the applied voltage.

30. The method according to claim 27, wherein the electrical device comprises a first plurality of contacts disposed over the first region and a second plurality of contacts disposed over the second region, wherein all of the first plurality of contacts is disposed along a single side of the first region.
